(19) United States
(12) Patent Application Publication
(10) Pub. No.: US 2021/0167044 A1
(43) Pub. Date: Jun. 3, 2021

(54) DISPLAY UNIT, DISPLAY APPARATUS, AND DISPLAY UNIT MANUFACTURING METHOD

(71) Applicant: Mitsubishi Electric Corporation, Chiyoda-ku, Tokyo (JP)

(72) Inventor: Satoru KIRIDOSHI, Tokyo (JP)

(73) Assignee: Mitsubishi Electric Corporation, Chiyoda-ku, Tokyo (JP)

(21) Appl. No.: 16/613,548

(22) PCT Filed: May 23, 2017
(86) PCT No.: PCT/JP2017/019136

§ 371 Date: Nov. 14, 2019

(51) Int. Cl. H01L 25/075; H01L 33/62; H01L 33/54; H05K 5/00

(52) U.S. Cl. CPC H01L 25/0753; H01L 33/62; H01L 2933/0066; H05K 5/0017; H01L 2933/005; H01L 33/54

(57) ABSTRACT

A display unit includes light emitting elements, a circuit board having a mount surface on which the light emitting elements are mounted and a waterproof film covering the light emitting elements and the mount surface. The mount surface includes a first region and a first recess. In the first region, the light emitting elements are mounted and the waterproof film is adhered. The waterproof film includes a first cover portion covering the first recess and having a surface area that is greater than an area of a first projection coverage obtained by perpendicular projection of the first recess onto an imaginary plane parallel to the first region.

### TECHNICAL FIELD

The present disclosure relates to a display unit, a display apparatus, and a method for manufacturing the display unit.

### BACKGROUND ART

A display apparatus with light emitting diode (LED) elements mounted on a board is known. For example, Patent Literature 1 describes a surface emitter including a board that is flexible. LED elements disposed on the board, and a top film affixed on the board. In Patent Literature 1 the top film is in intimate contact with the LED elements.

### CITATION LIST

### Patent Literature

Patent Literature 1: International Publication No. WO 2009/054153

### SUMMARY OF INVENTION

### Technical Problem

In the surface emitter of Patent Literature 1, the board and the top film expand or contract due to generation of heat from a power source or changes in ambient temperature. The board and the top film have different coefficients of linear expansion, thereby causing tensile stress to be repeatedly applied to the board or the top film. The top film, due to being thinner than the board, may be damaged by such repeatedly applied tensile stress. With the top film damaged, the surface emitter allows entry of rainwater or the like onto the board, which results in breakdown of the surface emitter.

In view of the above circumstances, an objective of the present disclosure is to provide a display unit, a display apparatus, and a method for manufacturing the display unit which can reduce possible damage to a waterproof film.

### Solution to Problem

According to the present disclosure, a display unit includes light emitting elements, a circuit board having a mount surface on which the light emitting elements are mounted, and a waterproof film covering the light emitting elements and the mount surface. The mount surface has a first region and a first recess. In the first region, the light emitting elements are mounted and the waterproof film is adhered. The waterproof film includes a first cover portion covering the first recess and having a surface area that is greater than an area of a first projection coverage obtained by perpendicular projection of the first recess onto an imaginary plane parallel to the first region.

### Advantageous Effects of Invention

According to the present disclosure, the surface area of the first cover portion of the waterproof film that covers the first recess is greater than the area of the first projection coverage obtained by perpendicular projection of the first recess onto the imaginary plane parallel to the first region, which enables tensile stress applied to the waterproof film to be relieved in the first cover portion, thereby reducing possible damage to the waterproof film.

### BRIEF DESCRIPTION OF DRAWINGS

FIG. 1 is a schematic diagram illustrating a front side of a display unit according to Embodiment 1 of the present disclosure;

FIG. 2 is a schematic cross-sectional diagram of the display unit, taken along line A-A of FIG. 1;

FIG. 3 is a schematic diagram illustrating a first cover portion and a first projection coverage in Embodiment 1 of the present disclosure;

FIG. 4 is a schematic diagram illustrating contraction of a circuit board and a waterproof film according to Embodiment 1 of the present disclosure;

FIG. 5 is a schematic diagram illustrating expansion of the circuit board and the waterproof film according to Embodiment 1 of the present disclosure;

FIG. 6 is a flow chart illustrating a method for manufacturing the display unit according to Embodiment 1 of the present disclosure;

FIG. 7 is a schematic diagram illustrating a front side of a display twit according to Embodiment 2 of the present disclosure;

FIG. 8 is a schematic cross-sectional diagram of the display unit, taken along line B-B of FIG. 7;

FIG. 9 is a perspective view of a case according to Embodiment 2 of the present disclosure;

FIG. 10 is a schematic diagram illustrating a second cover portion and a second projection coverage according to Embodiment 2 of the present disclosure;

FIG. 11 is a schematic diagram illustrating contraction of a waterproof film and the case according to Embodiment 2 of the present disclosure;

FIG. 12 is a schematic diagram illustrating expansion of the waterproof film and the case according to Embodiment 2 of the present disclosure;

FIG. 13 is a flow chart illustrating a method for manufacturing the display unit according to Embodiment 2 of the present disclosure;

FIG. 14 is a schematic diagram illustrating a front side of a display unit according to Embodiment 3 of the present disclosure;

FIG. 15 is a schematic cross-sectional diagram of the display unit taken along line C-C of FIG. 14;

FIG. 16 is a schematic diagram illustrating a second cover portion and a second projection coverage according to Embodiment 3 of the present disclosure;

FIG. 17 is a perspective view illustrating a display apparatus according to Embodiment 4 of the present disclosure;

FIG. 18 is a schematic diagram illustrating a first recess according to a variation of Embodiment 1 of the present disclosure;

FIG. 19 is a schematic diagram illustrating a first recess according to a variation of Embodiment 1 of the present disclosure;

FIG. 20 is a schematic diagram illustrating a first recess according to a variation of Embodiment 1 of the present disclosure;

FIG. 21 is a schematic diagram illustrating a second recess according to a variation of Embodiment 2 of the present disclosure;

FIG. 22 is a schematic diagram illustrating a second recess according to a variation of Embodiment 2 of the present disclosure; and

FIG. 23 is a schematic diagram illustrating a first recess and a first cover portion according to a variation of Embodiment 1 of the present disclosure.

### DESCRIPTION OF EMBODIMENTS

A display unit and a display apparatus according to embodiments of the present disclosure are described with reference to the drawings.

### Embodiment 1

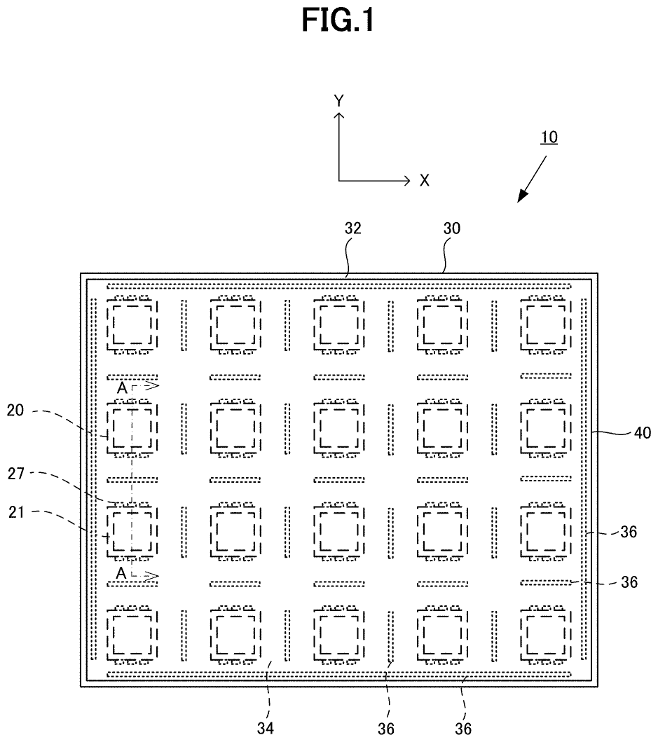

A display unit 10 according to Embodiment 1 of the present disclosure is described with reference to FIGS. 1 to 6. For ease of understanding, it is assumed in the description that the display unit 10 is installed outdoors, with a front side of the display unit 10 oriented perpendicularly to the ground. Here, a direction parallel to both the ground and the front side of the display unit 10 is defined as an X-axis direction. In addition, a direction perpendicular to the ground is defined as a Y-axis direction, and a direction perpendicular to the X-axis and Y-axis directions is defined as a Z-axis direction. These definitions of the axis directions are applied similarly to other embodiments. An adhesive layer 42 described later is omitted in FIG. 1 for ease of understanding.

As illustrated in FIG. 1, the display unit 10 includes light emitting elements 20, a circuit board 30 having a mount surface 32 on which the light emitting elements 20 are mounted, and a waterproof film 40 covering the light emitting elements 20 and the mount surface 32. The mount surface 32 of the circuit board 30 has a first region 34 and a first recess 36.

The display unit 10 is applicable as a unit installed outdoors, such as in a stadium or on a wall surface of a building.

The light emitting elements 20 are, for example, 3-in-1 surface mount LED elements. The light emitting elements 20 are mounted in the first region 34 on the mount surface 32 of the circuit board 30. The light emitting elements 20 are arranged in a 4 row by 5 column matrix.

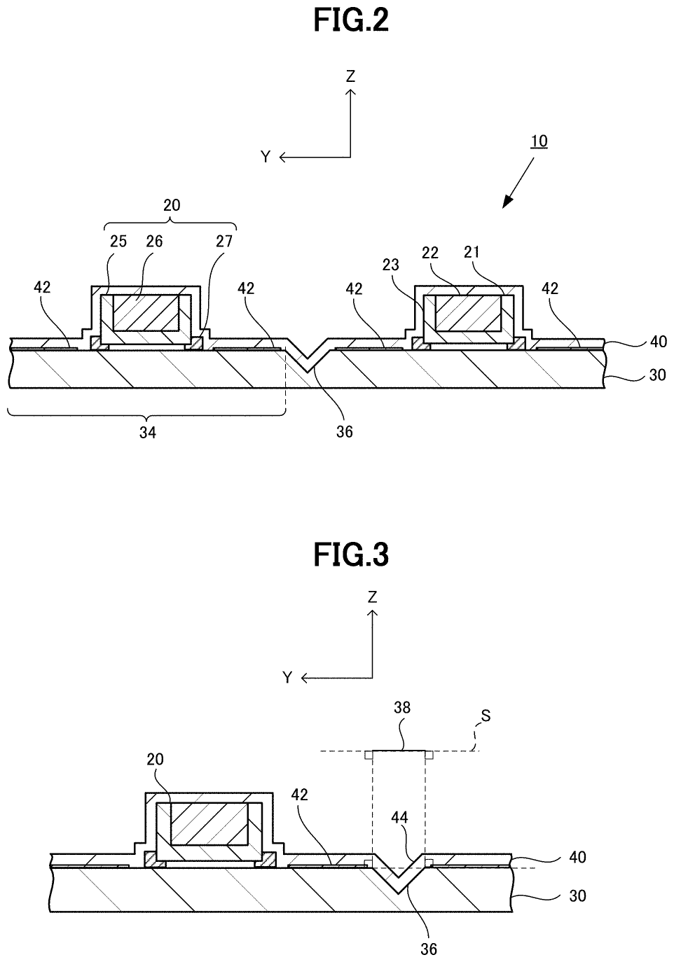

As illustrated in. FIG. 2, the light emitting elements 20 each have, on a flat top surface 21, a light exit face 22 that emits light. A face of the light emitting element 20 located on the front side of the display unit 10 is herein taken as the top surface 21 of the light emitting element 20. Faces of the light emitting element 20 perpendicular to the first region 34 are herein taken as side surfaces 23 of the light, emitting element 20.

The light emitting element 20 includes not-illustrated three light emitting chips, a package 25, a seal 26, and six electrodes 27.

The three light emitting chips emit light in corresponding colors of red, green, and blue. Emission intensities of the three light emitting chips are independently adjusted by power supplied via wiring of the circuit board 30 to the corresponding light emitting chips. Such adjustment of emission intensities achieves emission of different colors of light from the light emitting elements 20 at different intensities, which results in display of a color image on the display unit 10.

The package 25 is made of, for example, a white or black resin. Light emitting chips are mounted on a recessed portion of the package 25. The seal 26 seals the light emitting chips mounted on the recessed portion of the package 25. The seal 26 is a sealing resin filled in the recessed portion of the package 25. The sealing resin is, for example, a resin having light transmissivity, such as a silicone resin, an epoxy resin, an acrylic resin, or a polyester resin. The electrodes 27 supply power to the light emitting chips. Two electrodes 27 are connected to each of the light emitting chips. The two electrodes 27 connected to each light emitting chip are a positive electrode and a negative electrode. The electrodes 27 are electrically connected to the wiring of the circuit board 30 by soldering.

The circuit board 30 is made of an insulating resin. The insulating resin is, for example, a glass fiber filled epoxy resin. The circuit board 30 includes wiring and a drive integrated circuit (IC), both of which are not illustrated. The drive IC of the circuit board 30 supplies power to the light emitting elements 20 via the wiring of the circuit board 30 to drive the light emitting elements 20. The drive IC of the circuit board 30 is powered from an external power source of the display unit 10.

The circuit board 30 has the mount surface 32 on which the light emitting, elements 20 are mounted.

The mount surface 32 of the circuit board 30 includes the first region 34 and the first recess 36, as illustrated in FIGS. 1 and 2. The first region 34 of the mount surface 32 is a region in which the light emitting elements 20 are mounted and the waterproof film 40 is adhered. The first recess 36 is, for example, a V-shaped groove formed on the mount surface 32. As illustrated in FIG. 1, the first recesses 36 located, as viewed from the front side of the circuit board 30 on which the light emitting elements 20 are mounted, between the light emitting elements 20 mounted on the mount surface 32 each extend along edges of the top suffices 21 of the adjoining light emitting elements 20. In addition, the first recesses 36 located at the periphery of the mount surface 32 extend along an array of the light emitting elements 20. The depth of the first recess 36 from a level of the first region 34 is preferably deeper than the thickness of the waterproof film 40 described below.

The waterproof film 40 is made of a resin having light transmissivity. Examples of the resin having light transmissivity include a polyester resin, a polycarbonate resin, an acrylic resin, and an olefinic resin. The waterproof film 40 is pliable and flexible. The thickness of the waterproof film 40 is, for example, 50 μm to 500 μm, and from the flexibility and durability perspectives, preferably 150 μm to 300 μm.

The waterproof film 40 covers the light emitting elements 20 and the mount surface 32 of the circuit board 30. Such covering of the light emitting elements 20 and the mount surface 32 of the circuit board 30 with the waterproof film 40 renders the display unit 10 waterproof.

The waterproof film 40 is adhered in the first region 34 by the adhesive layer 42 that extends along the first recess 36 on both sides of the first recess 36, as illustrated in FIG. 2. Examples of the adhesive layer 42 include a silicone adhesive, an acrylic adhesive, and an urethane adhesive. The waterproof film 40 is in intimate contact with the top surface 21 and the side surfaces 23 of the light emitting element 20 and the first region 34. The waterproof film 40 is also in intimate contact with the first recesses 36, with the waterproof film 40 inserted into the first recesses 36. Such intimate contact of waterproof film 40 with the first region 34 and the first recesses 36 enables easy adaptation of the waterproof film 40 to contraction or expansion of the circuit board 30.

In the present embodiment, a portion of the waterproof film 40 covering the first recess 36 is referred to as a first cover portion 44, as illustrated in FIG. 3. The first cover portion 44 of the waterproof film 40 has a surface area that is greater than an area of a first projection coverage 38 obtained by perpendicular projection of the first recess 36 onto an imaginary plane S. The imaginary plane S is a plane parallel to the first region 34 of the mount surface 32.

Here, expansion and contraction of the circuit board 30 and the waterproof film 40 as well as tensile stress TS applied to the waterproof film 40 are described. For example, the circuit board 30 and the waterproof film 40 expand due to a rise in temperature outdoors where the display unit 10 is installed, and contract due to a drop in the temperature outdoors.

The description starts from a case in which the coefficient of linear expansion of the waterproof film 40 is higher than the coefficient of linear expansion of the circuit board 30.

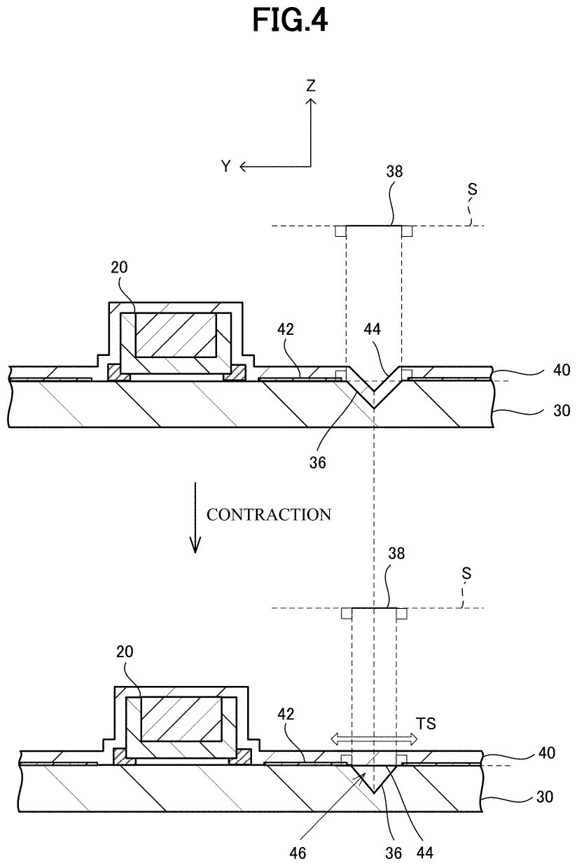

As the outdoor temperature drops, the waterproof film 40 attempts to contract more greatly than the circuit board 30. In the present embodiment, the surface area of the first cover portion 44 is greater than the area of the first projection coverage 38. Thus, as illustrated in FIG. 4, tensile stress TS is not applied to the waterproof film 40 until contraction of the circuit board 30 and the waterproof film 40 results in the surface area of the first cover portion 44 being the same as the area of the first projection coverage 38. In addition, since the waterproof film 40 contracts more greatly than the circuit board 30 until the surface area of the first cover portion 44 is the same as the area of the first protection coverage 38, the tensile stress TS applied to the waterproof film 40 becomes smaller. Thus the display unit 10 can relieve, in the first cover portion 44, the tensile stress TS applied to the waterproof film 40. This difference in contraction between the circuit board 30 and the waterproof film 40 creates a space 46 between the first recess 36 and the first cover portion 44.

In contrast, as the outdoor temperature rises, the waterproof film 40 expands more greatly than the circuit board 30, In this case, the tensile stress TS is not applied to the waterproof film 40.

The description is next directed to a case in which the coefficient of linear expansion of the circuit board 30 is higher than the coefficient of linear expansion of the waterproof film 40.

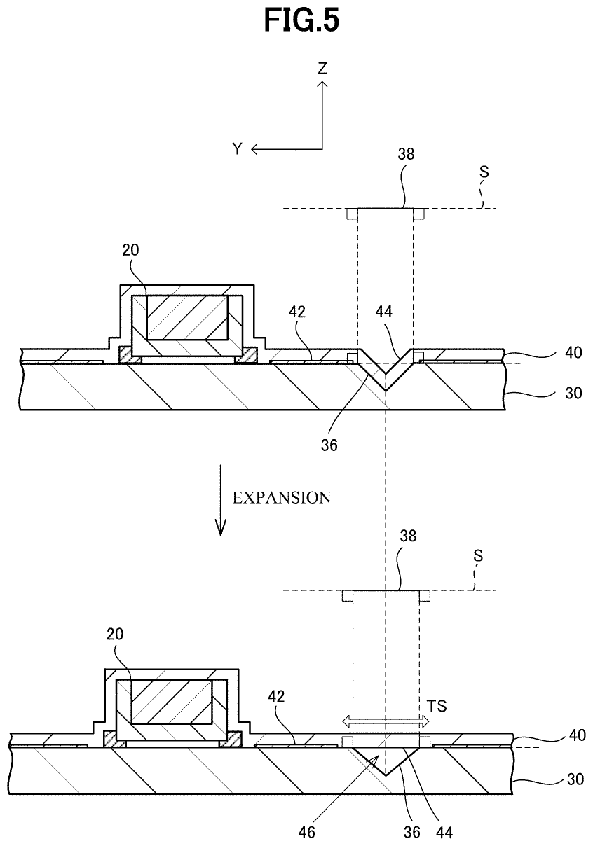

As the outdoor temperature rises, the circuit board 30 expands more greatly than the waterproof film 40. In the present embodiment, the surface area of the first cover portion 44 is greater than the area of the first projection coverage 38. Thus, as illustrated in FIG. 5, tensile stress TS is not applied to the waterproof film 40 until the surface area of the first cover portion 44 is the same as the area of the first projection coverage 38 by pulling of the waterproof film 40 by the circuit board 30. In addition, until the surface area of the first cover portion 44 is the same as the area of the first projection coverage 38, the circuit board 30 expands greatly compared to a difference between the surface area of the first cover portion 44 and the area of the first projection coverage 38 before rise in the outdoor temperature. The tensile stress TS applied to the waterproof film 40 thereby becomes smaller. Thus the display unit 10 can relieve, in the first cover portion 44, the tensile straws TS applied to the waterproof film 40. This difference in expansion between the circuit board 30 and the waterproof film 40 creates a space 46 between the first recess 36 and the first covet portion 44.

As the outdoor temperature drops, the circuit board 30 contracts more greatly than the waterproof film 40. In this case, the tensile stress TS is not applied to the waterproof film 40.

As described above, the surface area of the first cover portion 44 being greater than the area of the first projection coverage 38 relieves the tensile stress TS applied to the waterproof film 40. Through the relief of the tensile stress TS, the display unit 10 can reduce possible damage to the waterproof film 40.

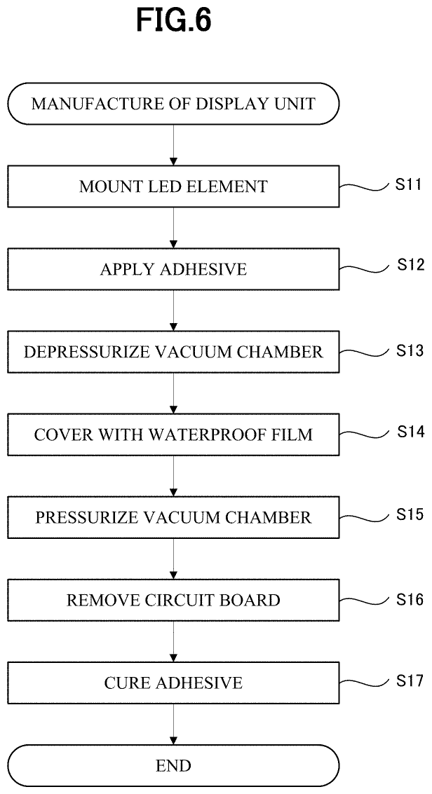

Next, a method for manufacturing the display unit 10 is described with reference to FIG. 6. FIG. 6 is a flow chart illustrating the method for manufacturing the display unit 10.

First of all, the light emitting elements 20, the circuit board 30 having the first recesses 36 on the mount surface 32, and the waterproof film 40 are prepared. Then the electrodes 27 of the light emitting elements 20 are reflow soldered to wiring of the circuit board 30, and each light emitting element 20 is mounted on the circuit board 30 in the first region 34 of the mount surface 32 (Step S11). Then an adhesive is applied to the first region 34 (Step S12). The applied adhesive extends along the first recess 36 on both the sides of the first recess 36.

The circuit board 30 with the adhesive applied and the waterproof film 40 are placed in a vacuum chamber, and then the vacuum chamber is depressurized (Step S13). Within the depressurized vacuum chamber, the light emitting elements 20 and the mourn surface 32 of the circuit board 30 are covered with the waterproof film 40 (Step S14).

Then the vacuum chamber is pressurized and the waterproof film 40 is thereby press fitted to the twin emitting elements 20 and the mount surface 32 (Step S15). Through this step, the waterproof film 40 is inserted into the first recess 36 and comes into intimate contact with the top surface 21 and the side surfaces 23 of each light emitting element 20 and the first region 34 and the first recesses 36 of the mount surface 32. The waterproof film 40 is adhered in the first region 34 to the mount surface 32 by the applied adhesive.

The vacuum chamber is allowed to return to atmospheric pressure, and the circuit board 30 with the waterproof film 40 attached is removed (Step S16). Finally, the applied adhesive is cured (Step S17).

The display unit 10 can be manufactured through the above steps.

As described above, the display unit 10 is rendered waterproof by the waterproof film 40. The surface area of the first cover portion 44 of the waterproof film 40 being greater than the area of the first projection coverage 38 relieves the tensile stress TS applied to the waterproof film 40 due to the difference in the coefficients of linear expansion between the circuit board 30 and the waterproof film 40. Since the tensile stress TS applied to the waterproof film 40 is relieved in the first cover portion 44, the display unit 10 can reduce possible damage to the waterproof film 40.

### Embodiment 2

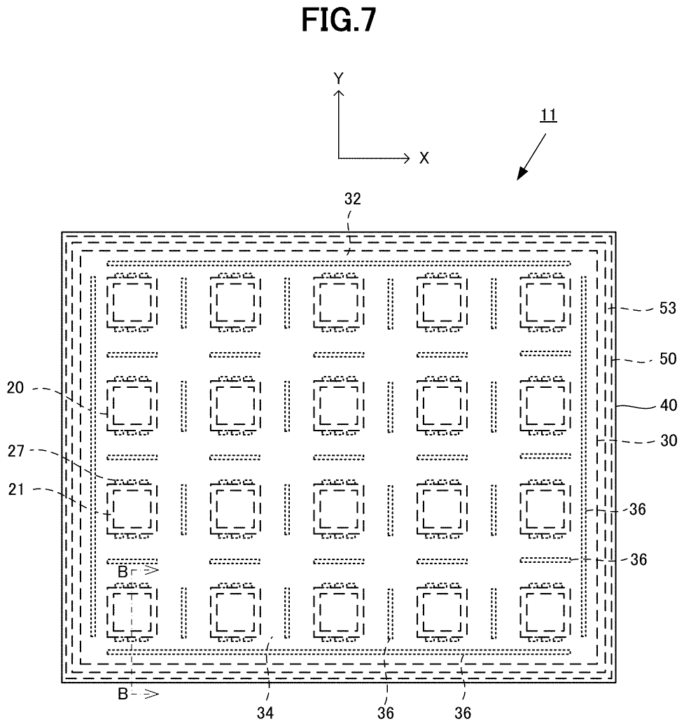

A display unit 11 according to Embodiment 2 of the present disclosure is described with reference to FIGS. 7 to 13.

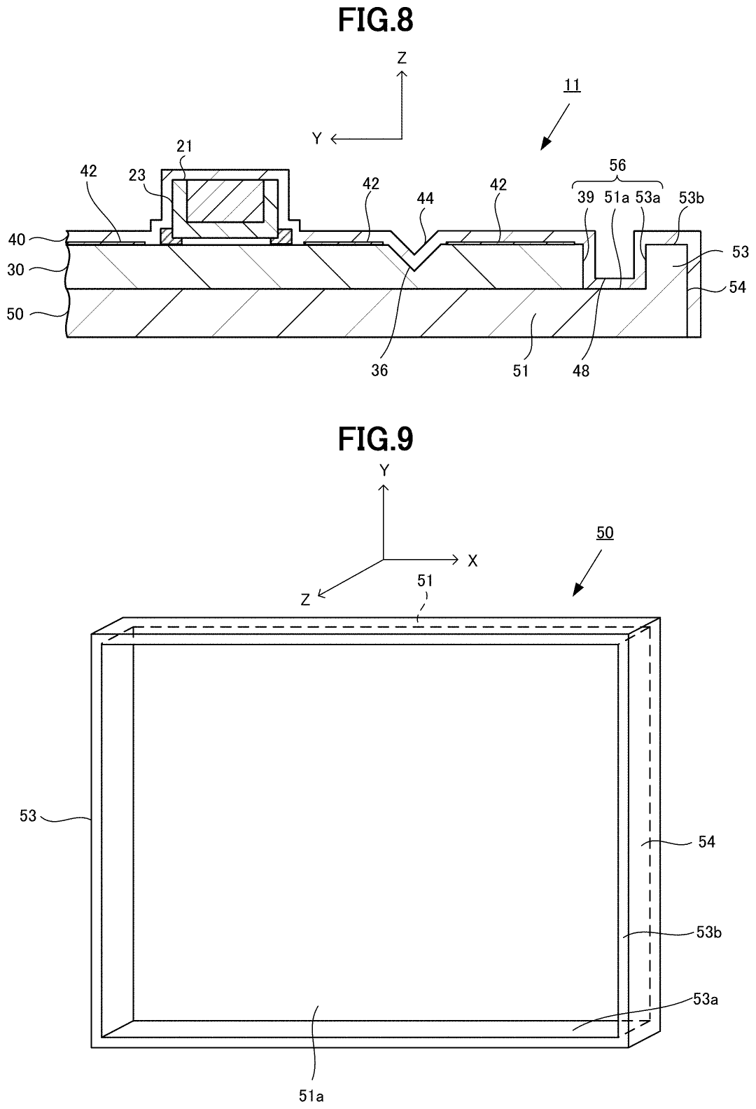

As illustrated in FIGS. 7 and 8, the display unit 11 further includes a case 50 that holds the circuit board 30, in addition to the light emitting elements 20, the circuit board 30, and the waterproof film 40. The light emitting elements 20 and the circuit board 30 have structures similar to those in Embodiment 1.

As illustrated in FIG. 9, the case 50 is a box-shaped enclosure that has an opening on a Z-axis direction side. The case 50 has a bottom plate 51 and side plates 53. As illustrated in FIGS. 7 and 8. the circuit board 30 on which the light emitting elements 20 are mounted is seated and held on the bottom plate 51. The side plates 53 surround the circuit board 50 seated on the bottom plate 51. As illustrated in FIG. 8, a second recess 50 is located between the side plates 53 and the circuit board 30. The second recess 56 has a side surface 39 of the circuit board 30, inner side surfaces 53a of the side plates 53, and an inner bottom surface 51a of the bottom plate 51. The second recess 56 is a rectangular-shaped groove.

The case 50 is made of a resin, such as a polycarbonate resin or an acrylic resin.

The waterproof film 40 is pliable and flexible, similarly to Embodiment 1. The waterproof film 40 is made of a resin having light transmissivity, such as a polyester resin, a polycarbonate resin, an acrylic resin, or an olefinic resin.

As illustrated in FIGS. 7 and 8, the waterproof film 40 covers the light emitting elements 20, the mount surface 32 of the circuit board 30, and the case 50. Such covering of the light emitting elements 20, the mount surface 32 of the circuit board 30, and the case 50 with the waterproof film 40 renders the display unit 11 waterproof.

The waterproof film 40 is adhered in the first region 34 to the circuit board 30 by the adhesive layer 42, similarly to Embodiment 1. The waterproof film 40 is adhered to top surfaces 53b of the side plates 53 of the case 50 and outer side surfaces 54 of the case 50 by a non-illustrated adhesive layer. The waterproof film 40 is in intimate contact with the top surface 21 and the side surfaces 23 of each light emitting element 20 and the first region 34 and the first recesses 36 of the mount surface 32, similarly to Embodiment 1. The waterproof film 40 is also in intimate contact with the second recess 56, with the waterproof film 40 inserted into the second recess 56. Such intimate contact of the waterproof film 40 with the first region 34, the first recesses 36, and the second recess 56 enables easy adaptation of the waterproof film 40 to contraction or expansion of the circuit board 30 and the case 50.

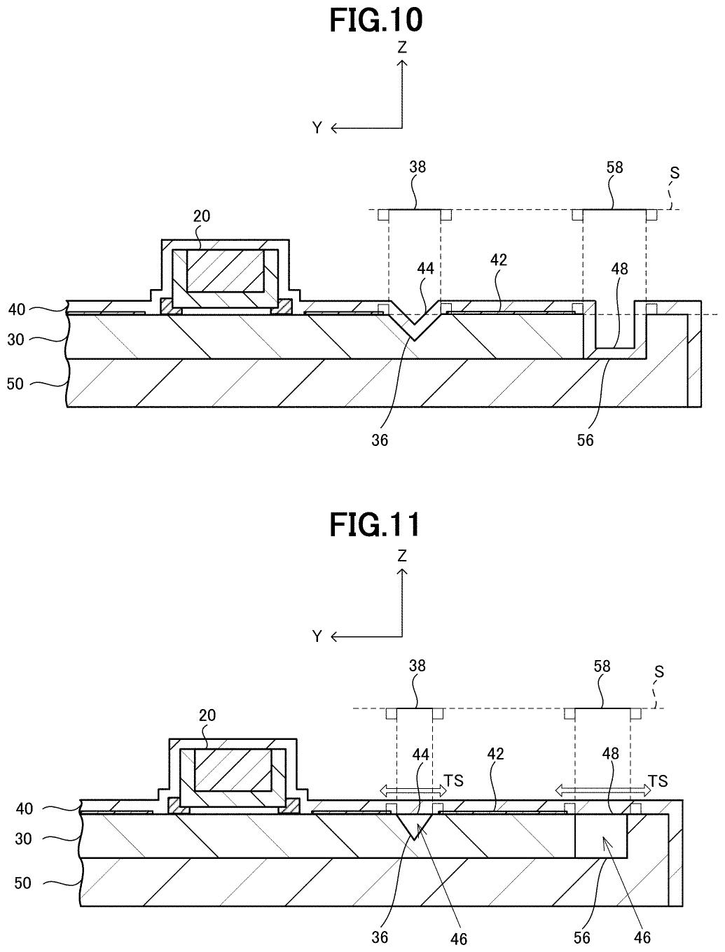

Similarly to Embodiment 1, a portion of the waterproof film 40 covering the first recess 36 is also referred to as the first cover portion 44 in the present embodiment. In addition, as illustrated in FIG. 10, a portion of the waterproof film 40 covering the second recess 56 is referred to as a second cover portion 48. Similarly to Embodiment 1, the surface area of the first cover portion 44 is greater than the area of the first projection coverage 38 obtained by perpendicular projection of the first recess 36 onto the imaginary plane S. A surface area of the second cover portion 48 is greater than an area of a second projection coverage 58 obtained by perpendicular projection of the second recess 56 onto the imaginary plane S. Similarly to Embodiment 1, the imaginary plane S is a plane parallel to the first region 34 of the mount surface 32.

Here, expansion and contraction of the waterproof film 40 and the case 50, as well as tensile stress TS applied to the waterproof film 40, are described. The relationship between the expansion and contraction of the circuit board 30 and the waterproof film 40 and the tensile stress TS applied to the waterproof film 40 is similar to that of Embodiment 1.

The description starts from a case in which the coefficient of linear expansion of the waterproof film 40 is higher than the coefficient of linear expansion of the case 50. For example, the waterproof film 40 and the case 50 expand due to a rise in temperature outdoors where the display unit 10 is installed and contract due to a drop in temperature outdoors.

As the outdoor temperature drops, the waterproof film 40 attempts to contract more greatly than the case 50. The surface area of the second cover portion 48 is greater than the area of the second projection coverage 58. Thus, as illustrated in FIG. 11, tensile stress TS is not applied to the waterproof film 40 until the surface area of the second cover portion 48 is the same as the area of the second projection coverage 58, similarly to the relationship between the circuit board 30 and the waterproof film 40 in Embodiment 1. In addition, since the waterproof film 40 contracts more greatly than the case 50 until the surface area of the second cover portion 48 is the same as the area of the second projection coverage 58, the tensile stress TS applied to the waterproof film 40 becomes smaller. Thus the display unit 11 can achieve relief of the tensile stress TS applied to the waterproof film 40 due to the difference in the coefficients of linear expansion between the waterproof film 40 and the case 50. This difference in contraction between the waterproof film 40 and the case 50 creates a space 46 between the second recess 56 and the second. cover portion 48.

As the outdoor temperature rises, the waterproof film 40 expands more greatly than the case 50. In this case, the tensile stress TS is not applied to the waterproof film 40.

The description is next directed to a case in which the coefficient of linear expansion of the case 50 is higher than the coefficient of linear expansion of the waterproof film 40.

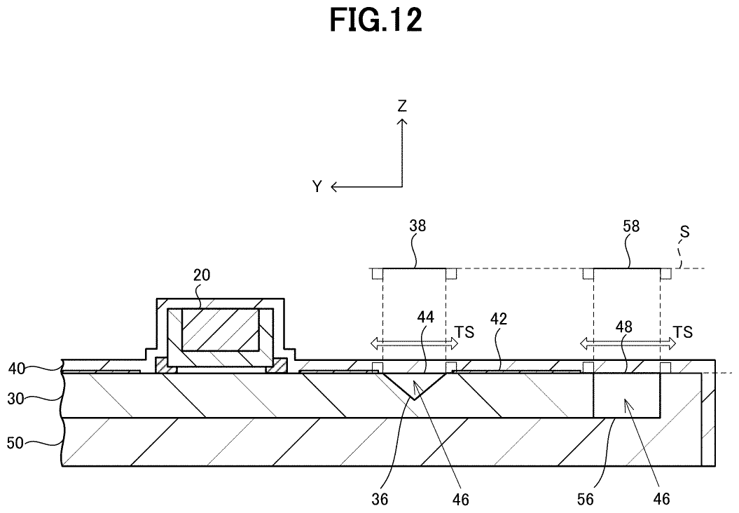

As the outdoor temperature rises, the case 50 expands more greatly than the waterproof film 40. The surface area of the second cover portion 48 is greater than the area of the second projection coverage 58. Thus, as illustrated in FIG. 12, tensile stress TS is not applied to the waterproof film 40 until the surface area of the second cover portion 48 is the same as the area of the second projection coverage 58 by pulling of the waterproof film 40 by the case 50 similarly to the relationship between the circuit board 30 and the waterproof film 40 in Embodiment 1. In addition, until the surface area of the second cover portion 48 is the same as the area of the second projection coverage 58, the case 50 expands greatly compared to a difference between the surface area of the second cover portion 48 and the area of the second projection coverage 58 before rise in the outdoor temperature. The tensile stress TS applied to the waterproof film 40 thereby becomes smaller. Thus the display unit 11 can achieve relief of the tensile stress TS applied to the waterproof film 40 due to the difference in the coefficients of linear expansion between the waterproof film 40 and the case 50. Here again, a space 46 is created between the second recess 56 and the second cover portion 48.

As described above, the surface area of the second cover portion 48 being greater than the area of the second projection coverage 58 relieves the tensile stress TS applied to the waterproof film 40 due to the difference in the coefficients of linear expansion between the waterproof film 40 and the case 50. In addition, similarly to Embodiment 1, the surface area of the first cover portion 44 of the waterproof film 40 being greater than the area of the first projection coverage 38 relieves the tensile stress TS applied to the waterproof film 40 due to the difference in the coefficients of linear expansion between the circuit board 30 and the waterproof film 40. Through the relief of the tensile stress TS, the display unit 11 can reduce possible damage to the waterproof film 40.

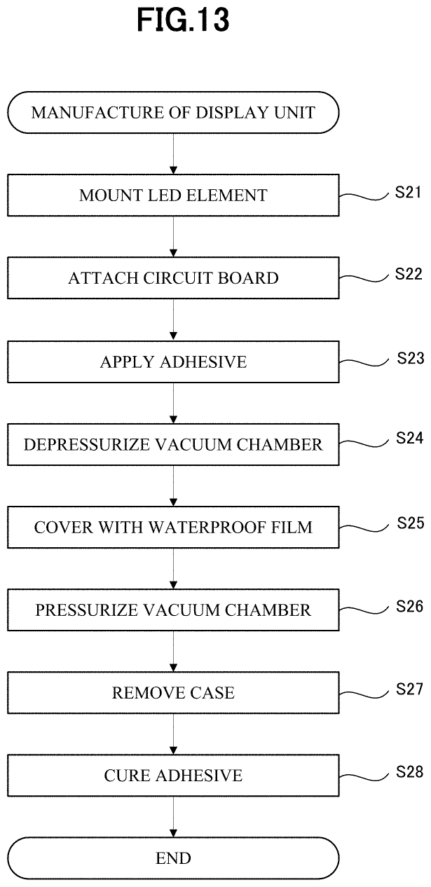

Next, a method for manufacturing the display unit is described with reference to FIG. 13. FIG. 13 is a flow chart illustrating the method for manufacturing the display unit 11.

First of all, the light emitting elements 20, the circuit board 30 having the first recesses 36 on the mount surface 32, and the waterproof film 40, and the case 50 are prepared. Then the electrodes 27 of the light emitting elements 20 are reflow soldered to wiring of the circuit board 30, and each emitting element 20 is mounted on the circuit board 30 in the first region 34 of the mount surface 32 (Step S21). Then the circuit board 30 on which the light emitting elements 20 an mounted is seated on the bottom plate 51 of the case 50, for example, with a gap between the side surfaces 39 of the circuit board 30 and the side plates 53 of the case 50. The circuit board 30 is then fastened by screws to the bottom plate 51 (Step S22). Through the steps, the circuit board 30 is mounted on the bottom plate 51 of the case 50, with the second recess 56 disposed between the side plates 53 and the circuit board 30.

Then an adhesive is applied to the first region 34 of the circuit board 30, the top surfaces 53b of the side plates 53 of the case 50, and the side surfaces 54 of the case 50 (Step S23). The adhesive applied to the first region 34 extends along the first recess 36 on both the sides of the first recess 36.

The case 50 with the adhesive applied and the waterproof film 40 are placed in a vacuum chamber and the vacuum chamber is depressurized (Step S24). Within the depressurized vacuum chamber, the light emitting elements 20, the mount surface 32 of the circuit board 30, and the case 50 are covered with the waterproof film 40 (Step S25).

Then the vacuum chamber is pressurized, and the waterproof film 40 is thereby press fitted to the light emitting elements 20, the mount surface 32, and the case 50 (Step S26). Through this step, the waterproof film 40 is inserted into the first recess 36 and the second recess 56, and comes into intimate contact with the top surface 21 and the side surfaces 23 of each light emitting element 20, the first region 34, the first recesses 36, and the second recess 56. The waterproof film 40 is adhered to the lust region 34 and the case 50 by the applied adhesive.

The vacuum chamber is allowed to return to atmospheric pressure, and the case 50 with the waterproof film 40 attached is removed (Step S27). Finally, the applied adhesive is cured (Step S28).

The display unit 11 can be manufactured through the above steps.

As described above, the display unit 11 is rendered waterproof by the waterproof film 40. The surface area of the second cover portion 48 of the waterproof film 40 being greater than the area of the second projection coverage 58 enables the display unit 11 to achieve relief of the tensile stress TS applied to the waterproof film 40 due to the difference in the coefficients of linear expansion between the waterproof film 40 and the case 50. In addition, similarly to Embodiment 1, the surface area of the first cover portion 44 of the waterproof film 40 being greater than the area of the first projection coverage 38 enables the display unit 11 to achieve relief of the tensile stress TS applied to the waterproof film 40 due to the difference in the coefficients of linear expansion between the circuit board 30 and the waterproof film 40. Since the tensile stress TS applied to the waterproof film 40 is relieved in the first cover portion 44 and the second cover portion 48, the display unit 11 can reduce possible damage to the waterproof film 40.

Since the circuit board 30 of the display unit 11 is held by the case 50, the display unit 11 can reduce warp of the circuit board 30. Since the display unit 11 includes the case 50 that holds the circuit board 30, easy handling is achieved in assembling of a display apparatus 15 described later.

### Embodiment 3

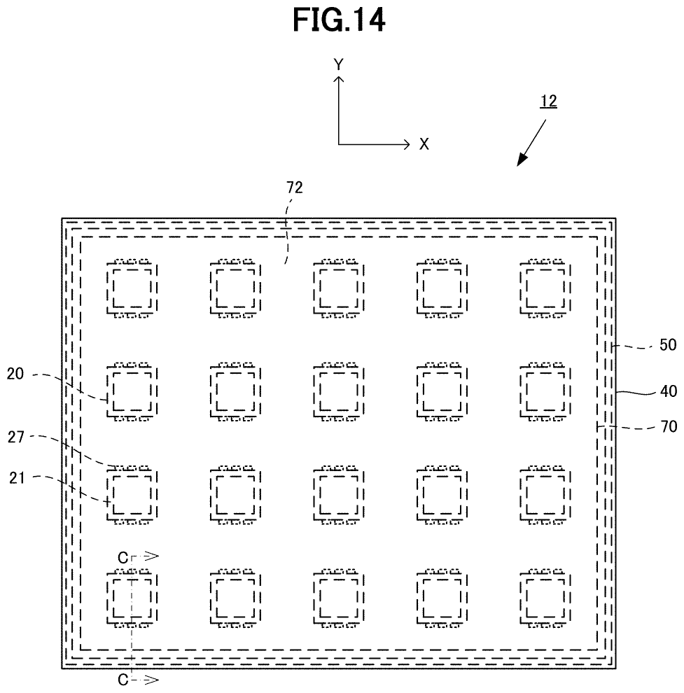

A display unit 12 according to the present embodiment is described with reference to FIGS. 14 to 16.

In Embodiment 2, the circuit board 30 of the display unit 11 has the first recess 36. A circuit board 70 in Embodiment 3 does not have the first recess 36.

The display unit 12 includes the light emitting elements 20, the circuit board 70, the waterproof film 40, and the case 50. The light emitting elements 20 and the case 50 have structures similar to those in Embodiment 2.

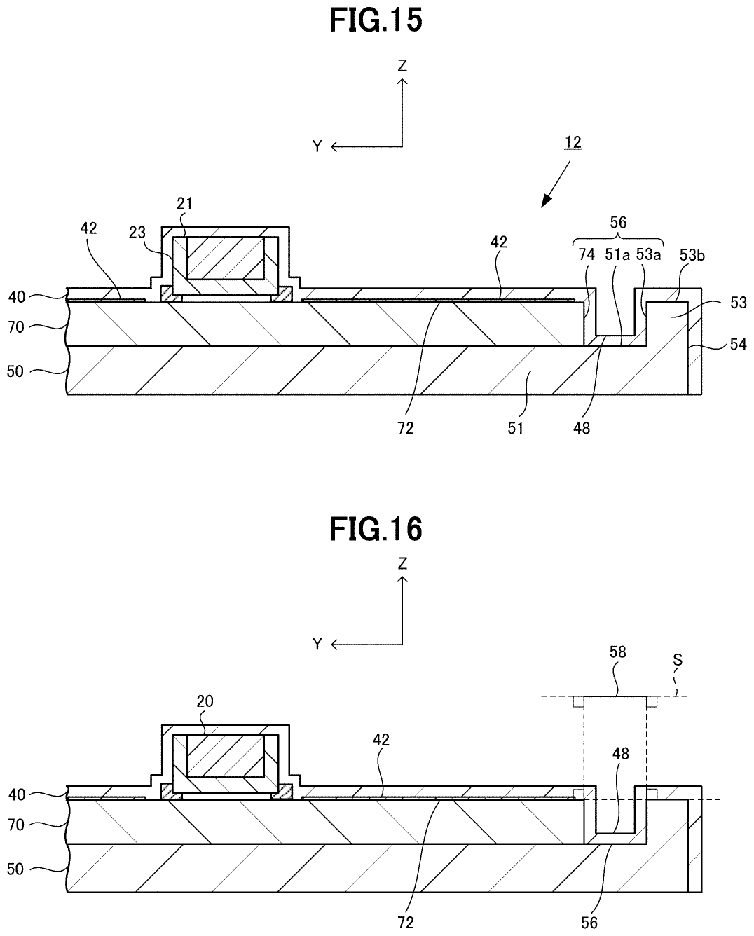

As illustrated in FIGS. 14 and 15, the circuit board 70 has a mount surface 72. The light emitting elements 20 are mounted on the mount surface 72 of the circuit board 70. The waterproof film 40 is adhered to the mount surface 72 of the circuit board 70. The structure of the circuit board 70 is the same as the circuit board 30 in Embodiments 1 and 2 in other respects.

The circuit board 70 is seated and held on the bottom plate 51 of the case 50, similarly to the circuit board 30 in Embodiment 2. As illustrated in FIG. 15, the circuit board 70 is seated, with the second recess 56 disposed between the side plates 53 of the case 50 and the circuit board 70. The second recess 56 has side surfaces 74 of the circuit board 70, inner side surfaces 53a of the side plates 53, and the inner bottom surface 51a of the bottom plate 51.

As illustrated in FIGS. 14 and 15, the waterproof film 40 covers the light emitting elements 20, the mount surface 72 of the circuit board 70, and the case 50. Such covering of the light emitting elements 20, the mount surface 72 of the circuit board 70, and the case 50 with the waterproof film 40 renders the display unit 12 waterproof.

The waterproof film 40 is adhered to the mount surface 72 of the circuit board 70, the top surfaces 53b of the side plates 53 of the case 50, and the outer side surfaces 54 of the case 50 by the adhesive layer 42 applied on the mount surface 72 and the adhesive layer applied on the top surfaces 53b and the side surfaces 54 of the case 50. The waterproof film 40 is in intimate contact with the top surface 21 and the side surfaces 23 of the light emitting element 20 and the mount surface 72 of the circuit board 70. The waterproof film 40 is also in intimate contact with the second recess 56, with the waterproof film 40 inserted into the second recess 56. Such intimate contact of the waterproof film 40 with the mount surface 72 of the circuit board 70 and the second recess 56 enables easy adaptation of the waterproof film 40 to contraction or expansion of the circuit board 30 and the case 50.

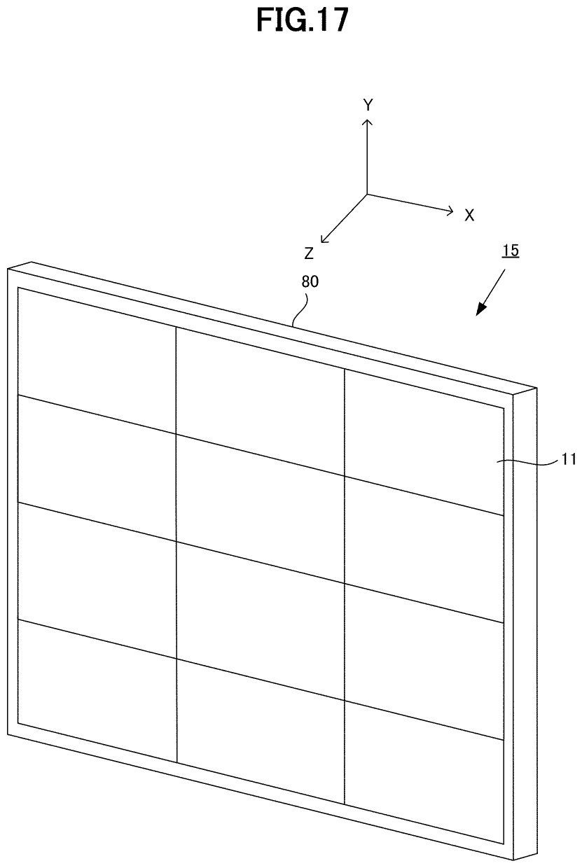

As illustrated in FIG. 16, the surface area of the second cover portion 48 of the waterproof film 40 is greater than the area of the second projection coverage 58 obtained by perpendicular projection of the second recess 56 onto the imaginary plane S. Thus, similarly to the display unit 11 in Embodiment 2, the display unit 12 can relieve the tensile stress TS applied to the waterproof film 40 due to the difference in the coefficients of linear expansion between the waterproof film 40 and the case 50. The second cover portion 48 of the waterproof film 40 is a portion of the waterproof film 40 covering the second recess 56, similarly to Embodiment 2. The imaginary plane S is a plane parallel to the mount surface 72.

The display unit 12 is manufactured by a manufacturing method similar to the method for manufacturing the display unit 11. Pressurizing the vacuum chamber (Step S26) renders the waterproof film 40 inserted into the second recess 56 to be in intimate contact with the top surface 21 and side surfaces 23 of each light emitting element 20, the mount surface 72 of the circuit board 70, and the second recess 56.

As described above, the display unit 12 is tendered waterproof by the waterproof film 40. The surface area of the second cover portion 48 of the waterproof film 40 being greater than the area of the second projection coverage 58 enables the display unit 12 to achieve relief of the tensile stress TS applied to the waterproof film 40 due to the difference in the coefficients of linear expansion between the waterproof film 40 and the case 50. Since the tensile stress TS applied to the waterproof film 40 is relieved in the second cover portion 48, the display unit 12 can reduce possible damage to the waterproof film 40. Since the circuit board 70 is held by the case 50, the display unit 12 can reduce warp of the circuit board 70. Since the display unit 12 includes the case 50 that holds the circuit board 70, easy handling is achieved in assembling of the display apparatus 15.

### Embodiment 4

A display apparatus 15 according to Embodiment 4 of the present disclosure is described with reference to FIG. 17.

A large-scale display apparatus 15 can be achieved by combination of multiple display units 10 to 12. The display apparatus 15 is applicable as a unit installed outdoors, such as in a stadium or on a wall surface of a building.

As illustrated in FIG. 17, the display apparatus 15 includes, for example, twelve display units 11 and an enclosure 80 that houses the twelve display unit 11.

The twelve display units 11 are arranged in a 4 row by 3 column matrix. The arranged display units 11 are housed in the enclosure 80. The display units 11 are, for example, fastened by screws to the enclosure 80. The enclosure 80 is, for example, a box-shaped metal housing.

Since the display units 11 can reduce possible damage to the waterproof film 40, the display apparatus 15 can also reduce possible damage to the waterproof film 40.

Although some embodiments attic present disclosure are described above, the present disclosure is not limited thereto, and various modifications can be made without departing from the scope of the invention.

For example, the light emitting elements 20 are not limited to LED elements, but may be laser diode (LD) elements. The LED elements are not limited to surface-mount LED elements, but rather may a lamp type LED element. The light emitting elements 20 are not limited to 3-in-1 type elements. The light emitting elements 20 may emit monochromatic light. The light emitting element 20 may include four or more light emitting chips.

The light emitting elements 20 can be disposed in any arrangement. For example, the light emitting elements 20 may be arranged in a 128 row by 128 column matrix or a 256 row by 256 column matrix. The light emitting elements 20 may be arranged in an orthorhombic lattice, hexagonal lattice, rectangular lattice, houndstooth, or in any other pattern. The spacing between the light emitting elements 20 can be freely selected.

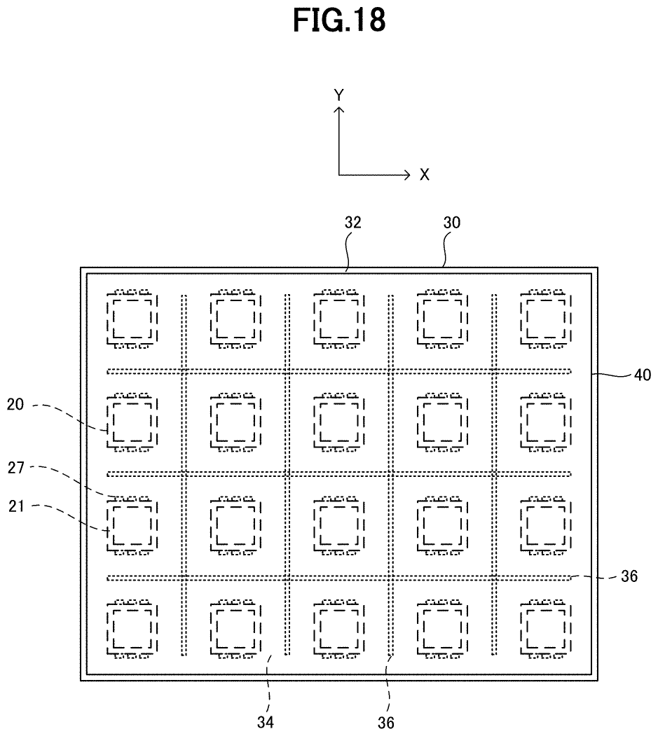

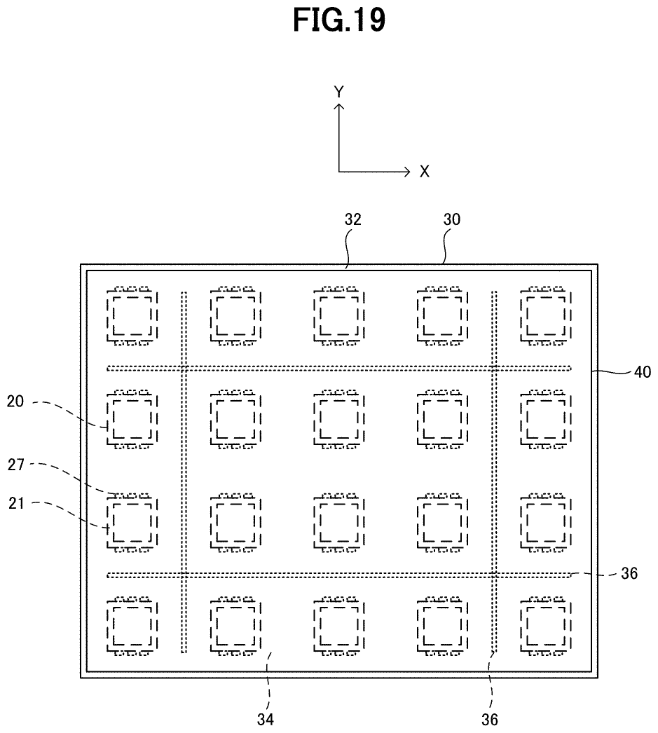

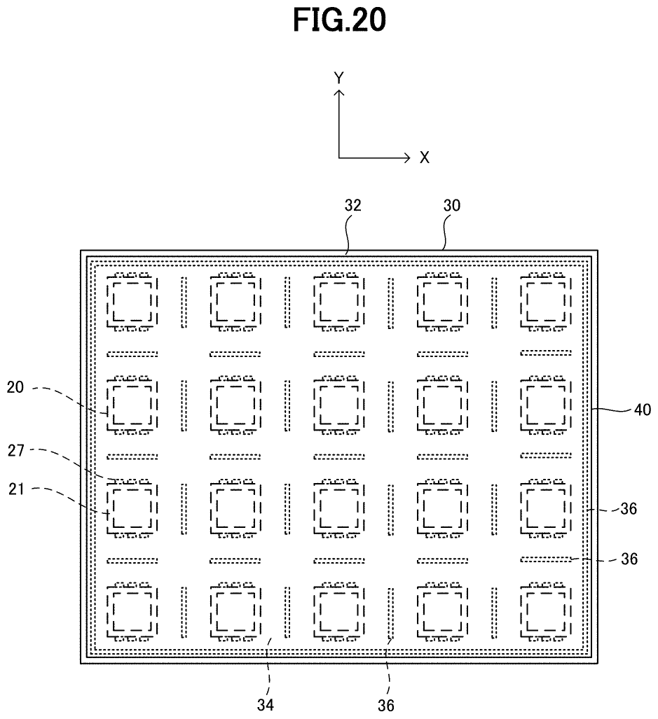

The Shape of the first recess 36 an the mount surface 32 in Embodiments 1 and 2 is not limited to a V shape. The first recess 36 may have any shape. The first recess 36 may have a rectangular shape, a U shape, or the like. The first recesses 36 may be arranged in X-axis and Y-axis directions, extending along an array ante light emitting elements 20, as illustrated in FIGS. 18 and 19. In addition, as illustrated in FIG. 20, the first recesses 36 may be arranged to surround the light emitting elements 20.

V-grooves cut in manufacturing the circuit board 30 may be used as the first recess 36. The V-groove is a V-shaped groove made for cutting off of a single circuit board 30 from a board containing multiple circuit boards 30. In manufacture of the circuit board 30, for example, the V-grooves may be cut, in addition to at the positions for cutting off the circuit board 30, in places where the first recesses 36 of the circuit board 30 are to be made, and the V-grooves may be used as the first recesses 36.

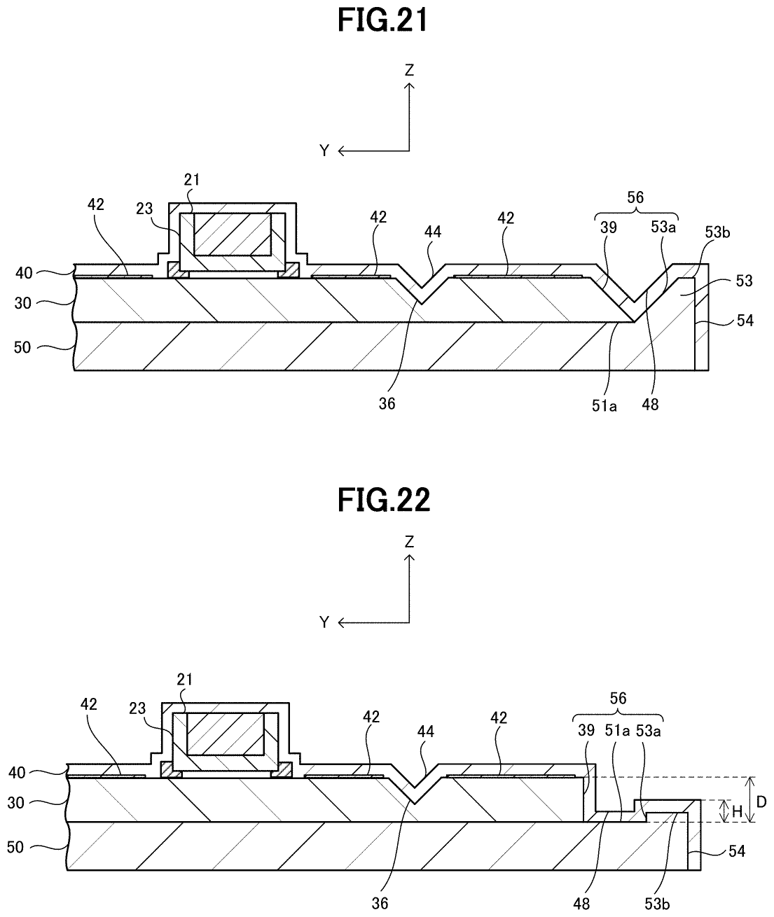

The shape of the second recess 56 in Embodiments 2 and 3 can be freely selected. For example, the second recess 56 may be a V-shaped groove having the side surface 39 of the circuit board 30 and the inner side surface 53a of the side plate 53, as illustrated in FIG. 21. This enables further easy adaptation of the waterproof film 40 to contraction or expansion of the case 50.

In addition, as illustrated in FIG. 22, the second recess 56 may have an asymmetric shape by setting of a height H of the side plate 53 of the case 50 from the bottom surface 51a of the case 50 to be lower than a thickness D of the circuit board 30. This enables further easy adaptation of the waterproof film 40 to contraction or expansion of the case 50. In addition, easy manufacturing of the case 50 can be achieved.

The waterproof film 40 has preferably thermoplastic properties. Heating the waterproof film 40 with the thermoplastic properties in manufacture of the display unit 10 to 12 enables easy press fitting of the waterproof film 40. In addition, the waterproof film 40 preferably has weathering resistance. The coefficient of linear expansion of the waterproof film 40 is preferably higher than the coefficient of linear expansion of the circuit board 30 and the coefficient of linear expansion of the case 50 since this can provide a wide range o selection of materials for these components.

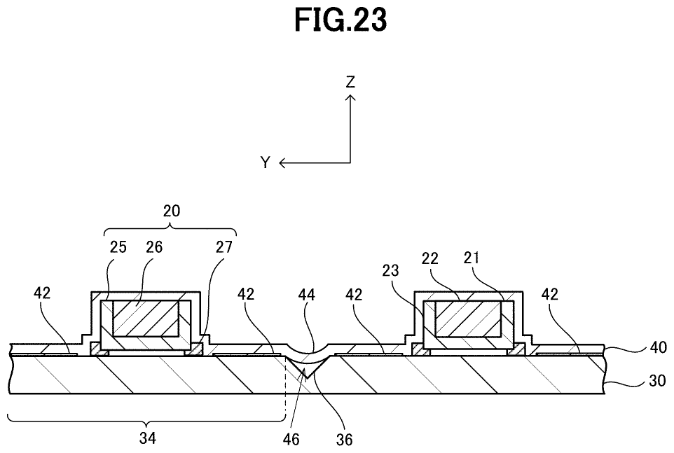

The waterproof film 40 may be adhered to the light emitting elements 20. The waterproof film 40 may be, for example, adhered to the light emitting elements 20 by an adhesive layer applied on the light emitting elements 20. As illustrated in FIG. 23, the first cover portion 44 of the waterproof film 40 may be disposed not to be in intimate contact with the first recess 36 to create a space 46 between the first cover portion 44 and the first recess 36. In addition, the second cover portion 48 of the waterproof film 40 may be disposed not to be intimate contact with the second recess 56 to create a space 46 between the second cover portion 48 and the second recess 56.

A louver or a mask plate for shielding from external light may be disposed on the waterproof film 40. The external light means light, including sunlight and illumination light, to enter the display unit 10 to 12 from the surroundings. Shielding the external light means reducing the external light entering into the light emitting elements 20 and the circuit board 30. The louver and the mask plate are, for example, fabricated by injection molding from a black resin.

The number and arrangement of the display units 10 included in the display apparatus 15 can be freely selected. The display apparatus 15 may include the display unit 11 or 12, instead of the display unit 10. The installation site of the display units 10 to 12 and the display apparatus 15 is not limited to the outdoors, but rather the display units 10 to 12 and the display apparatus 15 may be installed indoors, such as in a gymnasium or an indoor swimming pool.

### REFERENCE SIGNS LIST

10, 11, 12 Display unit
15 Display apparatus
20 Light emitting element
21 Top surface
22 Light exit face
23 Side surface
25 Package
26 Seal
27 Electrode
30, 70 Circuit board
32, 72 Mount surface
34 First region
36 First recess
38 First projection coverage
39, 74 Side surface
40 Waterproof film
42 Adhesive layer
44 First cover portion
46 Space
48 Second cover portion
50 Case
51 Bottom plate
51a Bottom surface
53 Side plate
53a Side surface
53b Top surface
54 Side surface
56 Second recess
58 Second projection coverage
80 Enclosure
TS Tensile stress
D Thickness
H Height
S Imaginary plane

1. A display unit comprising:
light emitting elements;
a circuit board having a mount surface on which the light emitting elements are mounted; and
a waterproof film covering the light emitting elements and the mount surface, wherein
the mount surface has a first recess and a first region in which the light emitting elements are mounted and the waterproof film is adhered, and
the waterproof film includes a first cover portion covering the first recess and having a surface area that is greater than an area of a first projection coverage obtained by perpendicular projection of the first recess onto an imaginary plane parallel to the first region.

2. The display unit according to claim 1, wherein the waterproof film is in intimate contact with the light emitting elements and the first region.

3. The display unit according to claim 1, wherein the first cover portion and the first recess define a space therebetween.

4. The display unit according to claim 1, wherein the first recess has a depth that is greater than a thickness of the waterproof film.

5. The display unit according to claim 1, further comprising:
a case to hold the circuit board, the case having side plates surrounding the circuitboard, wherein
the circuit board and the side plates of the case define a second recess therebetween,
the waterproof film covers the second recess, and
the waterproof film includes a second cover portion covering the second recess and having a surface area that is greater than an area of a second projection coverage obtained by perpendicular projection of the second recess onto the imaginary plane.

6. A display unit comprising:
light emitting elements:
a circuit board having a mount surface on which the light emitting elements are mounted;
a case to hold the circuit board, the case having side plates surrounding the circuit board; and
a waterproof film covering the mount surface, the light emitting elements, and the case and being adhered to the mount surface and the case, wherein
the circuit board and the side plates of the case define second recess therebetween, and
the waterproof film includes a second cover portion covering the second recess and having a surface area that is greater than an area of a second projection coverage obtained by perpendicular projection of the second recess onto an imaginary plane parallel to the mount surface.

7. The display unit according to claim 6, wherein the waterproof film is in intimate contact with the light emitting elements and the mount surface.

8. The display unit according to claim 5, wherein the second cover portion and the second recess define a space therebetween.

9. A display apparatus comprising a plurality of the display units according to claim 1.

10. A method for manufacturing a display unit, the method comprising:
mounting light emitting elements in a first region on a mount surface of circuit board, the mount surface including the first region and a first recess; and
adhering a waterproof film to the first region to cover the mount surface and the light emitting elements with the waterproof film inserted into the first recess.

11. A method for manufacturing a display unit, the method comprising:
mounting light emitting elements on a circuit board;
attaching the circuit board to a case to create a second recess between the circuit board and side plates of the case; and
adhering a waterproof film to the mount surface and the case to cover the light emitting elements, a mount surface of the circuit board on which the light emitting elements are mounted, and the case with the waterproof film inserted into the second recess.

12. The display unit according to claim 6, wherein the second cover portion and the second recess define a space therebetween.

13. A display apparatus comprising a plurality of the display units according to claim 6.
